(19) United States
(12) Patent Application Publication
(10) Pub. No.: US 2012/0212889 A1
(43) Pub. Date: Aug. 23, 2012

(54) ELECTRONIC EQUIPMENT AND DECORATIVE MEMBER USED FOR THE ELECTRONIC EQUIPMENT

(76) Inventors: Hiromi KANZAWA, Osaka (JP); Suguru Nakao, Hyogo (JP)

(21) Appl. No.: 13/398,266

(22) Filed: Feb. 16, 2012

(30) Foreign Application Priority Data
Feb. 22, 2011 (JP) 2011-035644

(51) Int. Cl. H05K 7/00

(52) U.S. Cl. 361/679.01

(57) ABSTRACT

Electronic equipment is electronic equipment having an outer cabinet that houses a device body, and the outer cabinet is provided with a decorative member. The decorative member includes a black first member with a small brightness, and a second member made of a light transmissive material and disposed on the first member while provided with a reflecting surface with projections and recesses on a surface facing the first member, and the second member is disposed on the first member so as to form a space between the reflecting surface and the first member.

### BACKGROUND OF THE INVENTION

1. Field of the Invention

The present invention relates to electronic equipment such as a plasma display panel or a liquid crystal display panel, and a decorative member used for the electronic equipment.

2. Description of the Related Art

In recent years, there have been widespread display device each using a plasma display panel, a liquid crystal panel or the like as a display device. Among them, the plasma display panel is broadly divided into an AC drive type and a DC drive type, and also into two kinds of discharge forms, a surface discharge type and a counter discharge type. Under present circumstances, a surface discharge type plasma display panel with a three-electrode structure has been mainstream from viewpoints of high definition, large screen and simplicity of manufacturing.

In the surface discharge type plasma display panel, a pair of substrates, each being transparent at least on a front surface side thereof, is disposed as opposed to each other such that a discharge space is formed between those substrates, and barrier ribs for partitioning the discharge space into a plurality of spaces are disposed inside the substrate. Further, in the plasma display panel, an electrode group is disposed on the substrate so as to generate discharge with respect to each discharge space partitioned by barrier ribs, and respective phosphors which emit red, green and blue light by discharge are provided with respect to each discharge space, to regularly dispose respective discharge cells for red, green and blue. Then, in the plasma display panel, during operation, the respective phosphors are excited by vacuum ultraviolet light with a short wavelength generated by discharge, and red, green and blue visible light are emitted respectively from arbitrary discharge cells for red, green and blue, to perform a color display.

A plasma display device using such a plasma display panel is particularly drawing attention in recent years since being capable of performing a fast display, having a wide angle of visibility, and being easy to increase in size as compared with a liquid crystal display device using the liquid crystal panel, as well as being a self-luminous type so as to have high display quality. Further, the plasma display device is in use for a variety of applications mainly as a large-screen display device in a place where a large number of people get together or as a main display device to entertain every family member at home.

Concerning the plasma display device, Japanese Unexamined Patent Publication No. 2005-331556 discloses an example where a panel mainly composed of glass is held on a front surface side of a chassis member made of metal such as aluminum, and a circuit board constituting a drive circuit for light emission of the panel is disposed on a rear surface side of the chassis member.

Meanwhile, concerning a conventional display device, Japanese Unexamined Patent Publication No. 2009-267575 discloses an outer cabinet of an assembly type which is divided into four pieces, and then brought together on the rear surface side. This outer cabinet has been devised in order to reduce manufacturing cost of an injection-molding mold. Although this outer cabinet is not a two-color injection molded article, two-color molten resins are injected into respective divided molds, whereby a gradation effect can be obtained.

However, in the display device, an outer cabinet with further improved design has been required.

### SUMMARY OF THE INVENTION

Electronic equipment of the present invention is electronic equipment comprising an outer cabinet that houses a device body, and the outer cabinet is provided with a decorative member. Then, the decorative member includes a black first member with a small brightness, and a second member made of light transmissive material and disposed on the first member while provided with a reflecting surface with projections and recesses on a surface facing the first member. The second member is disposed on the first member so as to form a space between the reflecting surface and the first member.

With such a configuration, it is possible to impart a more metal-like appearance to a member formed only of a resin, so as to add an upgrade image to the electronic equipment. Moreover, since the decorative member can be configured of the member formed only of a resin, it is possible to obtain a decorative member which is easily decomposable and excellent in recycling efficiency.

Further, the decorative member of the present invention is a decorative member used for electronic equipment, and the decorative member includes a black first member with a small brightness, and a second member made of light transmissive material and disposed on the first member while provided with a reflecting surface with projections and recesses on a surface facing the first member. Then, the second member may be disposed on the first member so as to form a space between the reflecting surface and the first member.

### BRIEF DESCRIPTION OF THE DRAWINGS

FIG. 1 is a front view showing an appearance of a liquid crystal display device according to an exemplary embodiment of the present invention.

FIG. 2 is a perspective view showing a state where a stand has been removed in the liquid crystal display device according to the exemplary embodiment of the present invention.

FIG. 3 is a block diagram showing a circuit block of an entire configuration of the liquid crystal display device according to the exemplary embodiment of the present invention.

FIG. 4 is a plan view shown with a back cabinet removed for explaining an example of disposition of the circuit block in the liquid crystal display device according to the exemplary embodiment of the present invention.

FIG. 5 is a plan view showing a schematic configuration of a front cabinet of the liquid crystal display device according to the exemplary embodiment of the present invention.

FIG. 6 is a sectional view taken along a cross section 6-6 of FIG. 5.

FIG. 7 is a schematic view showing an optical path of a light beam substantially vertically incident on a decorative member of the liquid crystal display device according to the exemplary embodiment of the present invention.

FIG. 8 is a schematic view showing an optical path of a light beam obliquely incident on the decorative member of the liquid crystal display device according to the exemplary embodiment of the present invention.

FIG. 9 is an explanatory view showing relations between light beams incident on an interface of a medium and output light beams.

FIG. 10 is a perspective view showing an example of a configuration in the case of constituting the decorative member by combining between the first member and the second member of the liquid crystal display device according to the exemplary embodiment of the present invention.

FIG. 11 is a perspective view showing an example of the configuration in the case of constituting the decorative member by combining between the first member and the second member of the liquid crystal display device according to the exemplary embodiment of the present invention.

FIG. 12 is a perspective view showing an example of the configuration in the case of constituting the decorative member by combining between the first member and the second member of the liquid crystal display device according to the exemplary embodiment of the present invention.

### DETAILED DESCRIPTION OF PREFERRED EMBODIMENT

### Exemplary Embodiment

Hereinafter, electronic equipment according to an exemplary embodiment of the present invention will be described with reference to the drawings by taking a liquid crystal display device as an example.

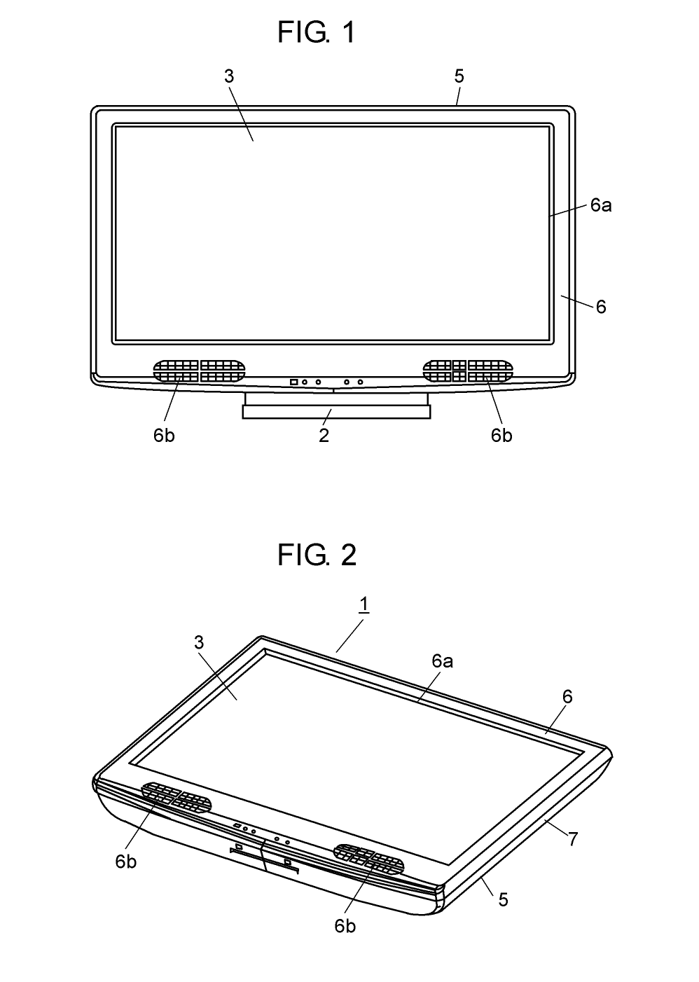

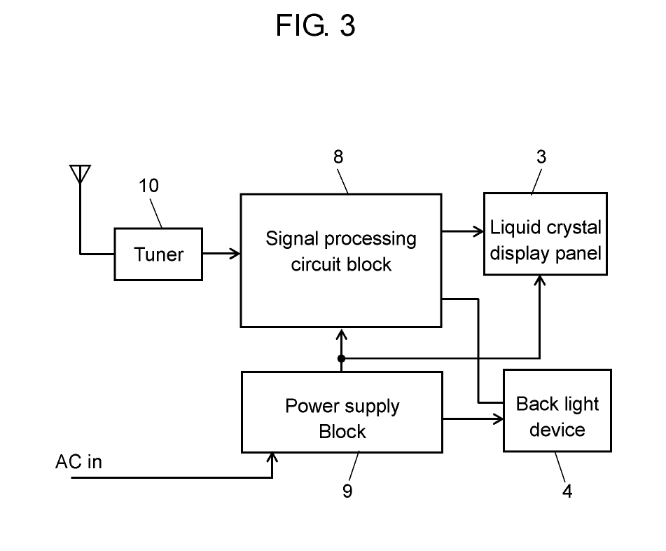

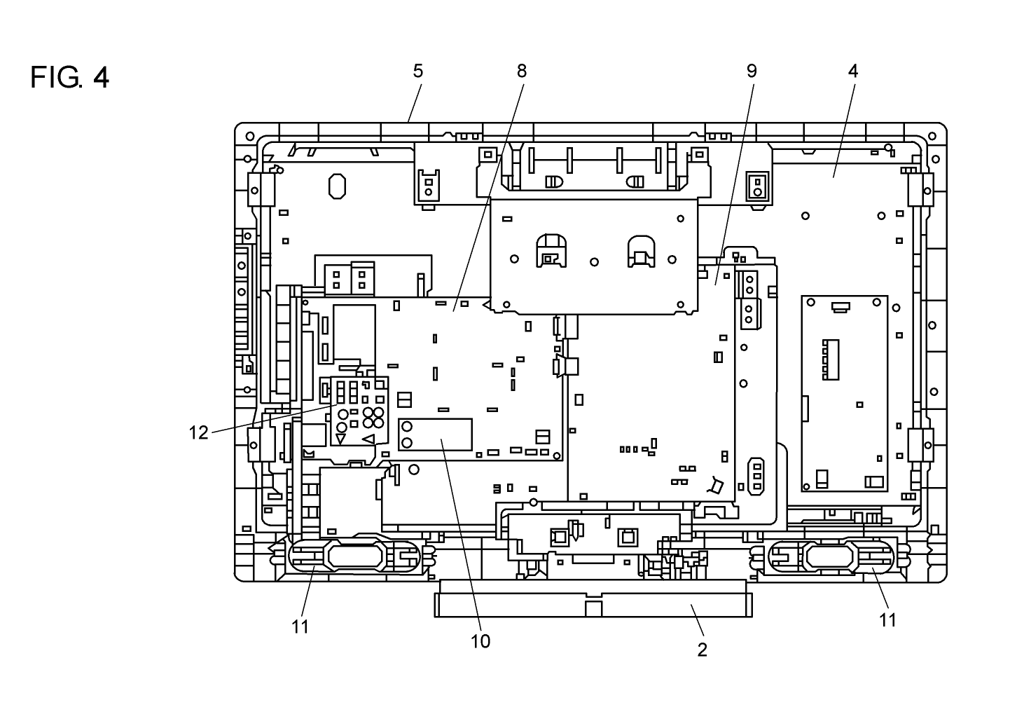

FIG. 1 is a front view showing an appearance of a liquid crystal display device according to the exemplary embodiment of the present invention. FIG. 2 is a perspective view showing a state where stand 2 has been removed in the liquid crystal display device according to the exemplary embodiment of the present invention. FIG. 3 is a diagram showing a circuit block of an entire configuration of the liquid crystal display device according to the exemplary embodiment of the present invention. FIG. 4 is a view shown with back cabinet 7 removed for explaining an example of disposition of the circuit block of the liquid crystal display device according to the exemplary embodiment of the present invention.

First, as shown in FIGS. 1 and 2, a liquid crystal display device as the electronic equipment has display device body 1 as a device body and stand 2 that holds display device body 1 in an erected state. A display module configured of liquid crystal display panel 3 as a flat type display panel and a back light device is housed into outer cabinet 5 made up of a resin molded article or the like, to constitute display device body 1. Further, outer cabinet 5 is configured of frame-shaped front cabinet 6 provided with opening 6a so as to correspond to an image displayed area of liquid crystal display panel 3, and back cabinet 7 combined with front cabinet 6. It is to be noted that front cabinet 6 is provided with speaker grille 6b for effectively emitting a sound of a speaker to the outside.

Moreover, as shown in FIGS. 3 and 4, a schematic configuration of the entire liquid crystal display device is that the device is provided with a drive circuit that displays an image on liquid crystal display panel 3, while being configured of signal processing circuit block 8 including a light control circuit for controlling lighting of back light device 4, liquid crystal display panel 3, back light device 4, power supply block 9 for supplying a power supply voltage to signal processing circuit block 8, tuner 10 that receives television broadcasting and supplies a reception signal to signal processing circuit block 8, and speaker 11 for outputting a sound. Furthermore, signal processing circuit block 8 and power supply block 9 are each configured by mounting components that constitute a circuit on a circuit board. The circuit board mounted with signal processing circuit block 8, power supply block 9, tuner 10 and the like is fitted so as to be disposed in a space between a rear surface of back light device 4 and back cabinet 7.

It is to be noted that the speaker is omitted in FIG. 3. Further, as shown in FIG. 4, outside signal inputting terminal 12 for inputting a video signal from an external device such as a DVD player into the liquid crystal display device is mounted in signal processing circuit block 8.

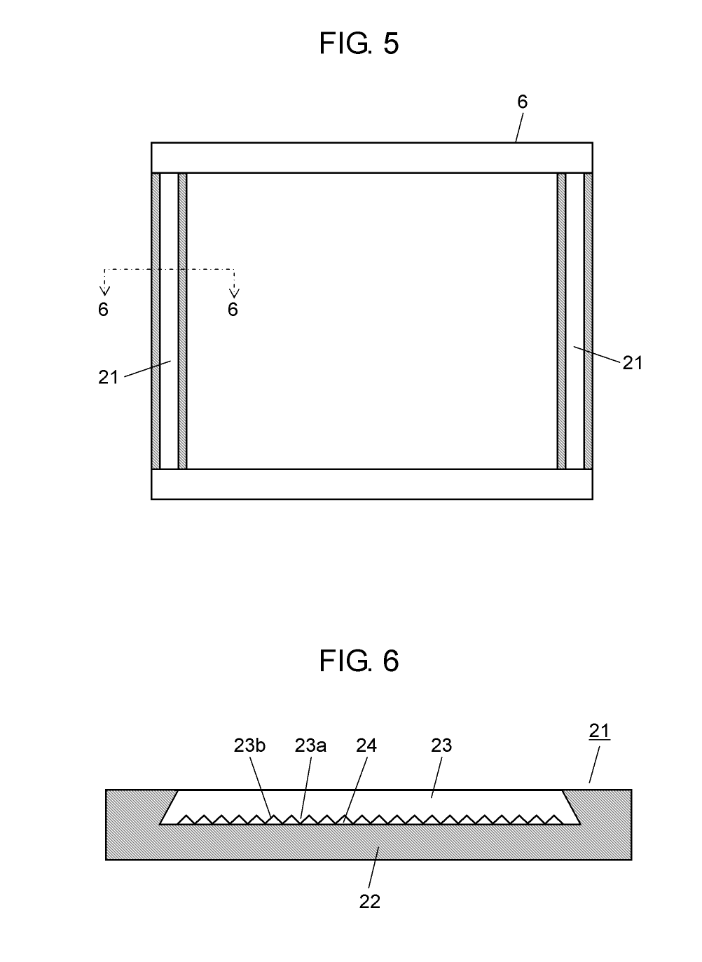

FIG. 5 is a plan view showing a schematic configuration of front cabinet 6 of the liquid crystal display device according to the exemplary embodiment of the present invention. FIG. 6 is a sectional view taken along a cross section 6-6 of FIG. 5.

As shown in FIGS. 5 and 6, decorative members 21 are disposed in right and left frame sections of front cabinet 6. Decorative member 21 is configured of first member 22 and second member 23. First member 22 is a black member with a small brightness, formed of a resin material such as ABS obtained by blending a black pigment such as carbon black into a base polymer. Second member 23 is disposed on first member 22, and formed by injection-molding or extrusion-molding a water-clear, light transmissive resin material such as acrylic or polycarbonate. Further, second member 23 has a smooth surface. Second member 23 has, on its rear surface facing first member 22, reflecting surface 23b provided with prism-shaped projections and recesses 23a, and each having a triangular cross section, at regular intervals with predetermined pitches. Further, first member 22 and second member 23 are disposed so as to form space 24 between reflecting surface 23b and first member 22.

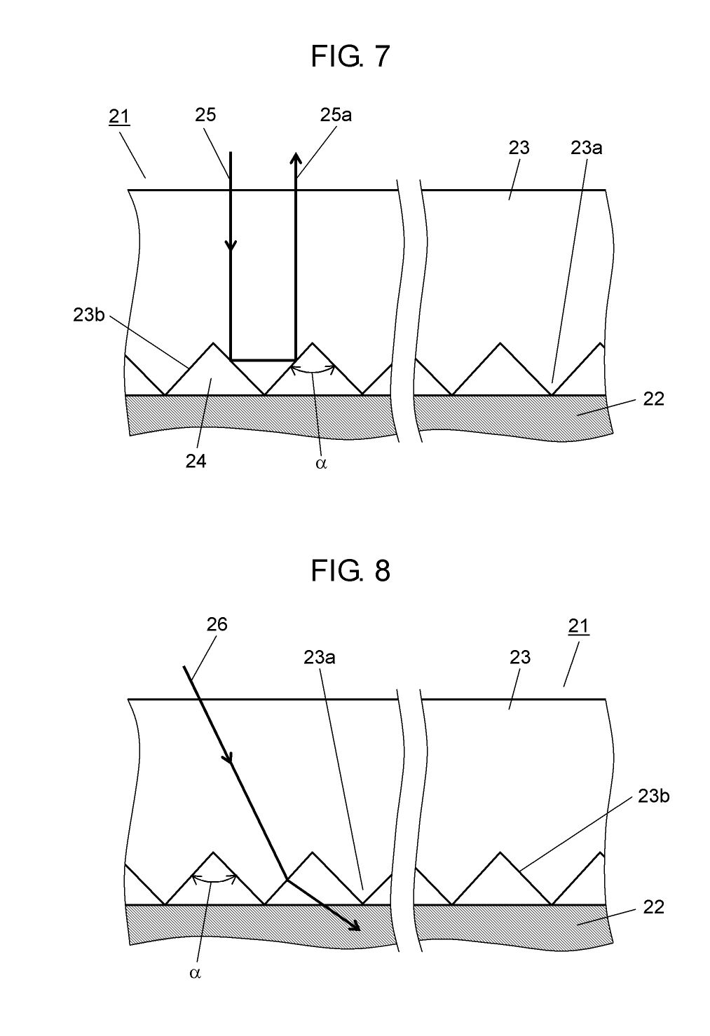

FIG. 7 is a schematic view showing an optical path of light beam 25 substantially vertically incident on decorative member 21 shown in FIG. 6. FIG. 8 is a schematic view showing an optical path of light beam 26 obliquely incident on decorative member 21 shown in FIG. 6. As shown in FIGS. 7 and 8, light beam 25 in every wavelength band having been substantially vertically incident on water-clear second member 23 of decorative member 21 is retroreflected by prism-shaped projections and recesses 23a provided on reflecting surface 23b, and output as reflecting light beam 25a from decorative member 21. Due to the reflection of light beam 25, a silver-like, namely, a metal-like, appearance design is obtained. On the other hand, light beam 26 obliquely incident on decorative member 21 is refracted by the prism provided on reflecting surface 23b and absorbed into first member 22.

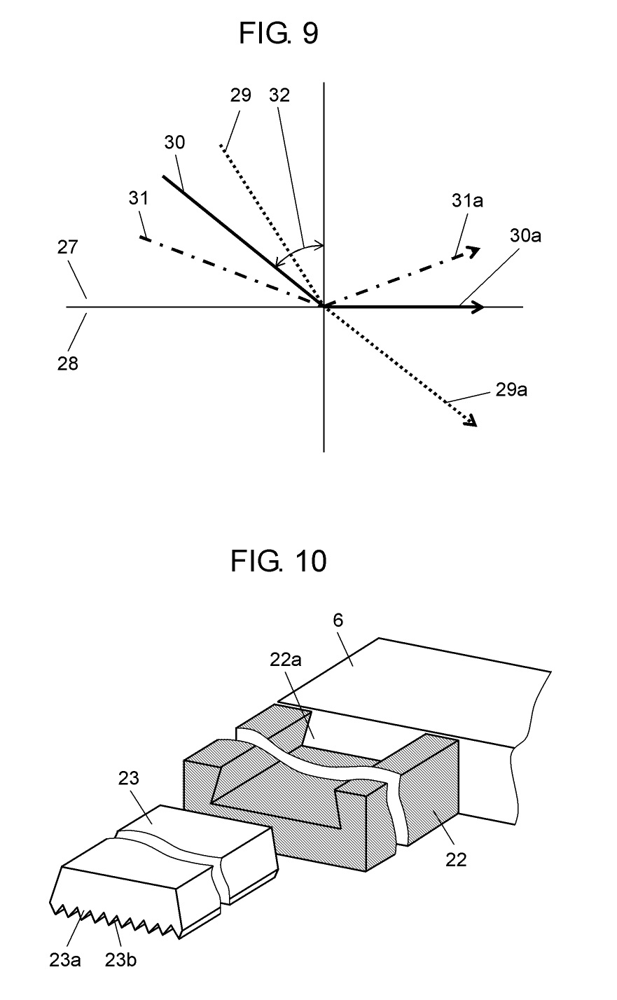

FIG. 9 is an explanatory view showing relations between light beams 29, 30, 31 incident on an interface of medium 27, and output light beams 29a, 30a, 31a. FIG. 9 shows medium 27 on the light-beam incident side and medium 28 on the light-beam output side. When a refractive index of medium 27 is larger than a refractive index of medium 28, light beams 29, 30, 31 incident on medium 27 are respectively output like light beam 29a, light beam 30a, light beam 31a. An incident angle of light beam 29 is smaller than a minimum incident angle of light for total reflection (i.e. critical angle) 32, and is thus transmitted. On the other hand, light beams 30, 31 are reflected on an interface of medium 28. When light is transmitted like light beam 29, medium 28 is transparent. However, with black first member 22 disposed below second member 23 having reflecting surface 23b as in the configuration of the present exemplary embodiment, even when light beam 26 incident on decorative member 21 is transmitted off the critical angle of reflecting surface 23b as shown in FIG. 8, light beam 26 is absorbed into black first member 22. Therefore, the inside of the device cannot be seen from decorative member 21.

Further, it is necessary to make the critical angle smaller in order to increase an angle area at which decorative member 21 has a metal-like appearance. Hence, according to a definitional formula for the critical angle, a small air layer with a minimum refractive index of 1.0 is desired as a portion adjacent to reflecting surface 23b. Accordingly, in decorative member 21, most of incident light is retroreflected due to disposition of second member 23 on first member 22 so as to form space 24 between reflecting surface 23b and first member 22, and hence it is possible to make large the angle at which decorative member 21 has a metal-like appearance when seen obliquely.

It is to be noted that in the present exemplary embodiment, an angle a of a tip of reflecting surface 23b in a triangular shape is formed so as to be not larger than 60 degrees, and it is thus possible to make large an angle at which decorative member 21 has a metal-like appearance when it is seen obliquely.

FIGS. 10 to 12 are perspective views each showing an example of the configuration in the case of constituting decorative member 21 by combining between first member 22 and second member 23 of the liquid crystal display device according to the exemplary embodiment of the present invention.

In the example shown in FIG. 10, first member 22 of decorative member 21 is provided with a fitting groove 22a into which second member 23 is to be fitted. Then, an angle of a wall surface rising from a bottom of fitting groove 22a to an upper surface side thereof is made an acute angle smaller than 90 degrees. On the other hand, an outside wall of second member 23 in its width direction is shaped to have an inclined surface corresponding to fitting groove 22a.

Accordingly, as shown in FIG. 6, fitting second member 23 into fitting groove 22a of first member 22 allows both of them to be fixed so as to constitute decorative member 21 with ease, and furthermore without use of an adhesive tape or an adhesive which would impair the design.

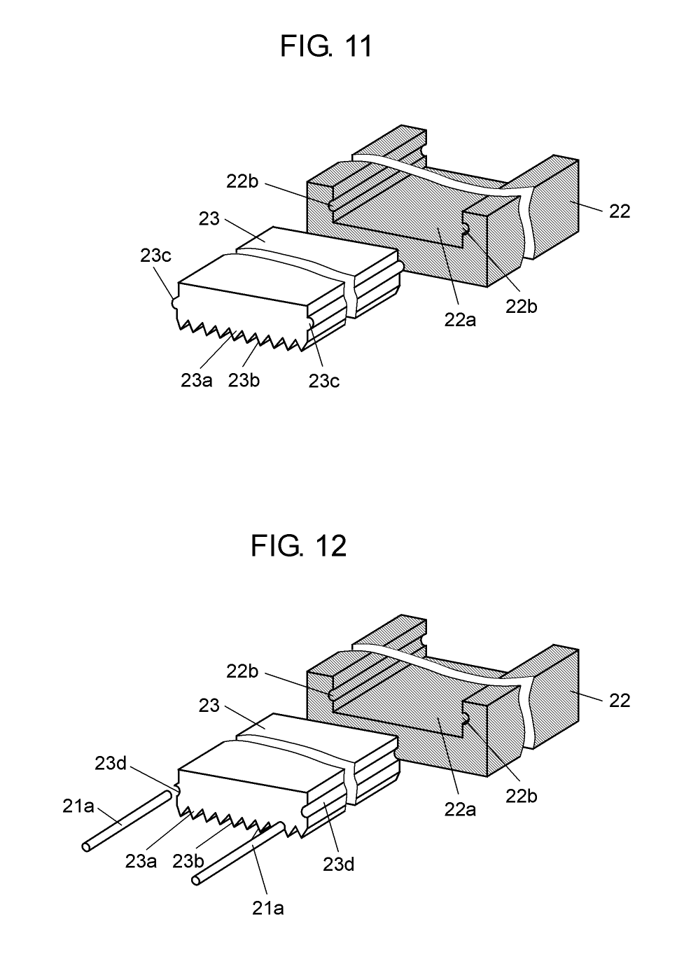

In the example shown in FIG. 11, concave portion 22b is provided on an inside wall surface of fitting groove 22a of first member 22. Meanwhile, convex portion 23c to be fitted with concave portion 22b is provided on an outside wall surface of second member 23 in its width direction.

Further in the example shown in FIG. 12, concave portion 22b is provided on the inside wall surface of fitting groove 22a of first member 22. Meanwhile, concave portion 23d is also provided on the outside wall surface of second member 23 in its width direction. Subsequently, bar-like connecting member 21a is inserted into a long hole formed by concave portion 22b and concave portion 23d, and connecting member 21a connects between first member 22 and second member 23.

Also in the examples shown in FIGS. 11 and 12, it is possible to fix first member 22 and second member 23 so as to constitute decorative member 21 with ease, and furthermore without use of an adhesive tape or an adhesive which would impair the design.

As described above, in the liquid crystal display device as the electronic equipment in the exemplary embodiment of the present invention, outer cabinet 5 is provided with decorative member 21. Then, decorative member 21 has black first member 22 with a small brightness and second member 23 made of a light transmissive material, disposed on first member 22 and provided with reflecting surface 23b with projections and recesses on a surface facing first member 22. Second member 23 is disposed on first member 22 so as to form space 24 between reflecting surface 23b and first member 22. This can result in imparting a more metal-like appearance to a member formed only of a resin, so as to add an upgrade image to outer cabinet 5. Moreover, since the decorative member can be configured of the member formed only of a resin, it is possible to obtain a decorative member which is easily decomposable and excellent in recycling efficiency.

What is claimed is:

1. Electronic equipment comprising an outer cabinet that houses a device body, wherein
the outer cabinet is provided with a decorative member,
the decorative member includes a black first member with a small brightness, and a second member made of light transmissive material and disposed on the first member while provided with a reflecting surface with projections and recesses on a surface facing the first member, and
the second member is disposed on the first member so as to form a space between the reflecting surface and the first member.

2. The electronic equipment according to claim 1, wherein a shape of each one of the projections and recesses of the reflecting surface is triangular in cross section.

3. The electronic equipment according to claim 1, wherein an angle of a tip of the reflecting surface in the triangular shape is not larger than 60 degrees.

4. The electronic equipment according to claim 1, wherein the first member is provided with a fitting groove into which the second member is to be fitted.

5. A decorative member used for electronic equipment, wherein the decorative member comprises a black first member with a small brightness, and a second member made of light transmissive material and disposed on the first member while provided with a reflecting surface with projections and recesses on a surface facing the first member, and
the second member is disposed on the first member so as to form a space between the reflecting surface and the first member.
